(19) United States
(12) Patent Application Publication
(10) Pub. No.: US 2008/0190760 A1
(43) Pub. Date: Aug. 14, 2008

(54) RESPUTTERED COPPER SEED LAYER

(75) Inventors: XIANMIN TANG, San Jose, CA (US); Arvind Sundarrajan, San Jose, CA (US); Daniel Lubben, San Jose, CA (US); Qian Luo, San Jose, CA (US); Tza-Jing Gung, San Jose, CA (US); Anantha Subramani, San Jose, CA (US); Hua Chung, San Jose, CA (US); Xinyu Fu, Fremont, CA (US); Rongjun Wang, Cupertino, CA (US); Yong Cao, San Jose, CA (US); Jick Yu, San Jose, CA (US); John Forster, San Francisco, CA (US); Praburam Gopalraja, San Jose, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/838,796

(22) Filed: Aug. 14, 2007

Related U.S. Application Data
(60) Provisional application No. 60/888,893, filed on Feb. 8, 2007.

(51) Int. Cl. C23C 14/32

(52) U.S. Cl. 204/192.17

(57) ABSTRACT

An integrated copper deposition process, particularly useful for forming a copper seed layer in a narrow via prior to electrochemical plating of copper, including at least one cycle of sputter deposition of copper followed by sputter etching of the deposited copper, preferably performed in a same sputter chamber. The deposition is performed under conditions promoting high copper ionization fractions and strong wafer biasing to draw the copper ions into the via. The etching may be done with argon ions, preferably inductively excited by an RF coil around the chamber, or by copper ions, which may be formed with high target power and intense magnetron or by use of the RF coil. Two or more cycles of deposition/etch may be performed. A final flash deposition may be performed with high copper ionization and low wafer biasing.

### RELATED APPLICATION

This application claims benefit of provisional application 60/888,893, filed Feb. 8, 2007.

### FIELD OF THE INVENTION

The invention relates generally sputter deposition in the formation of semiconductor integrated circuits. In particular, the invention relates to a combination of sputter deposition and sputter etching in forming liner layers.

### BACKGROUND ART

Magnetron sputtering has long been used in the deposition of horizontally extending layers of metallization such as aluminum and copper. More recently, magnetron sputtering has been adapted to the more challenging task of depositing liner layers in high aspect-ratio holes such as inter-level electrical contacts, also called vias. A via 10 for a copper metallization, illustrated in the cross-sectional view of FIG. 1, is formed over a conductive feature 12 at the surface of a lower dielectric layer 14. An upper dielectric layer 16 is deposited over the lower dielectric layer 14 and its conductive feature and a via hole 18 is etched through the upper dielectric layer 18 down to the conductive feature 12. With succeeding generations of advanced integrated circuits, the width of the via hole 18 has been decreasing to below 65 nm while the thickness of the dielectric layers 14, 16 has been held substantially constant at about 500 to 1000 nm. As a result, the aspect ratio of the via hole 18 has been significantly increasing. Filling metallization and especially liner layers into the high aspect-ratio holes presents great challenges.

A conventional dielectric material for both dielectric layers 14, 16 has been silicon dioxide (silica) but more recently low-k dielectric materials have been developed, some of which are composed of silicon oxycarbide having a significant carbon content. Further, the dielectric material may be made porous to obtain very low values of dielectric constant. To prevent copper from migrating into the dielectric material, a thin barrier layer 20 is deposited on a via sidewall 22 and usually also on a field region 24 on top of the upper dielectric layer 16. The barrier layer 20 preferably is not formed on a via bottom 26 so as to reduce contact resistance to the underlying conductive feature 12. A conventional barrier material for copper metallization is tantalum, either a single Ta layer or a Ta/TaN barrier layer. Ruthenium tantalum is also being developed as a barrier material. Techniques have been developed to selectively coat the barrier layer 20 into the narrow via hole 18 by magnetron sputtering of a tantalum, ruthenium, or ruthenium tantalum target. The nitride layer is similarly deposited by reactive sputtering in which nitrogen is additionally admitted into the sputter chamber.

Electrochemical plating (ECP) is typically used to fill the via hole 18 with copper although electroless plating is possible. ECP copper usually requires a copper seed layer both to serve as a plating electrode and to nucleate the ECP copper. Accordingly, a copper seed layer 30 is deposited on the via sidewall 22 and the field region 24 as well as the via bottom 26 in somewhat conformal layers. Again, magnetron sputtering techniques have been developed for depositing copper fulling these demanding requirements. These techniques rely upon a high ionization fraction of the sputtered copper atoms and electrical biasing of the wafer to draw the copper ions deep within the via hole 18 to deposit a substantial bottom portion 32 and an acceptably thick sidewall portion 34. The sidewall coverage is accomplished in part by energetic copper ions which are accelerated by the wafer bias and resputter, that is, sputter etch, copper from the bottom portion 32 onto the sidewall portion 34. The copper sputtering may also produce a relatively thick field portion 36 on top of the field region 24. Significant overhangs 38 develop on the corners of the field portion 36 at the top of the via hole 18 producing a narrow throat 40 We have observed that the overhangs 38 mostly develop above the barrier layer in the field region 20. That is, the narrowest portion of the throat 40 is above the bottom of the copper field portion 36.

To complete the metallization, copper is plated, for example, by electroplating, into the via hole 18. The ECP copper overfills the via hole 18 and deposits over the field region 24. Chemical mechanical polishing (CMP) is used to remove the copper over the barrier layer 20 outside the via hole 18, thereby leaving only copper in the via hole 18.

Metallization structures are often more complex than the via structure 18 of FIG. 1. Vias are typically formed to have a generally square or circular shape with the narrowest width possible. On the other hand, a deep trench may be formed having a relatively narrow dimension across the trench and a much longer dimension along the trench. An even more complicated structure of a dual-damascene interconnect structure, as illustrated in the cross sectional view of FIG. 2 includes vias 42 in a lower part of the dielectric layer 16 and wider, horizontally extending trenches 44 in the upper part connecting the vias 42 and providing contacts to yet higher metallization levels. The barrier and seed depositions and the ECP fill are performed in a single sequence for both the vias 42 and trenches 44. The conductive feature 12 in FIG. 1 may be the trench of a dual-damascene metallization in the lower dielectric layer 14. However, a copper seed layer 46 sputter deposited in the dual-damascene structure forms significant overhangs 48 at the corner of the floor of the floor of the trench 44 and the vias 42. The overhangs 48 cause difficulty in coating the via sidewalls over which they project because of the narrowed throat they create at the top of the via holes 42.

Returning to the simpler via structure of FIG. 1, although the comments apply nearly equally to the dual-damascene structure, the overhangs 38 tend to limit the performance of the sputter process for depositing copper seed. If the copper seed layer 30 is relatively thick, the overhangs 38 grow and the throat 40 shrinks, thereby increasing the effective aspect ratio for sputtering into the via hole 18 with the result that it is difficult to achieve sufficient via sidewall coverage. A narrow throat 40 also impedes the flow of electrolyte in the plating process. If the thickness of the copper seed layer 30 is reduced, the overhang problem is reduced. However, the thickness of the narrowest portion of the sidewall portion 34 may be insufficient and the sidewall portion 34 may become discontinuous to form gaps to expose the underlying barrier material, which poorly nucleates ECP copper. Such gaps in the copper seed layer 30 may cause voids in the electroplated copper adjacent the via sidewall 22.

Some believe that increasing both the copper ionization fraction and the wafer bias causes the copper ions to mill the developing overhangs. We believe, however, that energetic copper ions do not limit the growth of the overhangs. Instead, the energetic copper ions tend to resputter the copper from the overhangs to portions of the sidewall underlying the overhangs. As a result, the resputtering effectively pushes the overhangs down into the via hole. While the extent of the overhangs may be somewhat reduced, if the overhangs are pushed below the level of the field barrier, the overhang etching may expose a facet of the barrier layer at the corner of the via hole and etch through it, thereby locally destroying the barrier.

Another solution is needed for reducing the size of the overhangs and improving the ability to fill high aspect-ratio vias.

Further but related problems arise when the dielectric material is a carbon-containing low-k dielectric material such as Black Diamond II available from Applied Materials, Inc. of Santa Clara, Calif. Such materials do not afford the highly anisotropic etch available in silica. The problems worsen when the dielectric material is made porous to further decrease the dielectric constant. As illustrated with exaggeration in the cross-sectional view of FIG. 3, the patterned etching through an etching mask into a dielectric layer 50 of porous carbon-containing low-k material tends to be not completely anisotropic but instead to be somewhat isotropic to produce a via hole 52 with a distinctly concave sidewall 54 with an acute corner 56 underlying the edge of the etching mask. Sputtering a copper seed layer onto the concave sidewall 54 suffers from difficulties similar to those experienced with overhangs. As a result, it is possible that the most protected portions of the concave sidewall 54 are not completely coated with the copper seed layer deposited by conventional sputter deposition.

Yet further, the vertical structure to be etched through during the dielectric etch process may be more complicated than previously illustrated. As illustrated in the cross-sectional view of FIG. 4, a hard mask layer 60 of, for example, titanium nitride (TiN) is often deposited over the unpatterned upper dielectric layer 16. It is etched into a pattern according to an overlying photoresist mask and is then used as a hard mask for the more extensive etching of the upper dielectric layer 16 to form the via hole 18. Also, an etch stop layer 62 of, for example, silicon nitride (SiN) layer is often deposited over the lower dielectric layer 14 and its conductive feature 12. Its composition is chosen to be not readily etched by the dielectric etch so that the dielectric layer 16 can be over etched, to assure that the metal of the conductive feature 12 is not etched by the energetic ions of the dielectric etch, and to further assure that a misaligned mask does not cause the lower dielectric layer 14 to be significantly etched. However, the otherwise anisotropic dielectric etch is likely to form a recess 64 in the dielectric material adjacent the hard mask layer 60 and another recess 66 at the interface with the etch stop layer 62. It is difficult for a conventional copper seed sputter deposition to reach inside these concave recesses 64, 66.

The sputter deposition of copper seed layer may not completely coat sides of the concave sidewall 54 or recesses 64, 64 resulting in the same problems discussed before for overhangs.

### SUMMARY OF THE INVENTION

A copper seed layer is formed in a via or other hole in a semiconductor integrated circuit by a multiple-step process. First, copper is deposited in a plasma sputtering process under conditions creating a high fraction of copper ions and the wafer is biased to accelerate the copper ions and attract some of them deep into the hole. The copper deposits at least at the bottom of the hole and in the field region and overhangs may form over the hole. Secondly, an argon plasma is formed and the wafer is biased to accelerate the argon ions and to attract at least some of them deep in the hole. The energetic argon ions resputter copper at the bottom of the via onto the via sidewalls and also sputter etch the field region to reduce the size of the overhangs. The overhangs should not be etched below the top of the hole.

A final copper sputter deposition may be performed prior to electroplating copper into the remaining portion of the hole.

The sputter deposition and etch process may be repeated to fill more of the hole before copper electroplating. If the sputter and etch process are repeated sufficiently, the hole may be filled with copper by the last deposition step to fill the hole so that chemical mechanical polishing may immediately follow the sputter deposition.

The sputter deposition and etch processes may be performed in a single plasma sputter chamber. For example, the chamber may be equipped with an RF coil. Sputter deposition is favored at low argon pressure, high target power, and low coil power. Sputter etching is favored at higher argon pressure, lower target power, and higher coil power. The substrate should be strongly biased for at least the initial copper deposition steps and for the argon sputter etching steps.

### BRIEF DESCRIPTION OF THE DRAWINGS

FIG. 1 is a cross-sectional view of a conventional via having significant overhangs created in the copper seed layer.

FIG. 2 is a cross-sectional view of a conventional dual-damascene interconnect structure also having overhangs in the copper seed layer.

FIG. 3 is a cross-sectional view of a via produced by a partially isotropic dielectric etch.

FIG. 4 is a cross-sectional view of a via including a hard mask and an etch stop layer.

FIG. 5 is a cross-sectional view of a sputter chamber useful for practicing the inventive method.

FIG. 6 is a functional and schematic cross-sectional view of the sputter chamber of FIG. 5.

FIG. 7 is an idealized cross-sectional view of a via after only sputter deposition.

FIG. 8 is an idealized cross-sectional view of the via of FIG. 7 after argon sputter etching.

FIGS. 9 and 10 are representations of scanning electron micrographs (SEMs) of test structures corresponding to FIGS. 7 and 8.

FIG. 11 is a representation of an SEM of a via in a test structure after sputter deposition.

FIGS. 12, 13, and 14 are representations of SEMS of the via of FIG. 11 after progressively more argon sputter etching.

FIG. 15 is a flow diagram of two embodiments of filling a via hole with copper including electroplating.

FIGS. 16, 17, 18, and 19 are schematic cross-sectional view of a via hole developed during the methods of FIG. 15.

FIG. 20 is a flow diagram of filling a via hole with copper but not including electroplating.

FIG. 21 is a schematic cross-sectional view of the via hole of FIG. 20 after completion of copper filling.

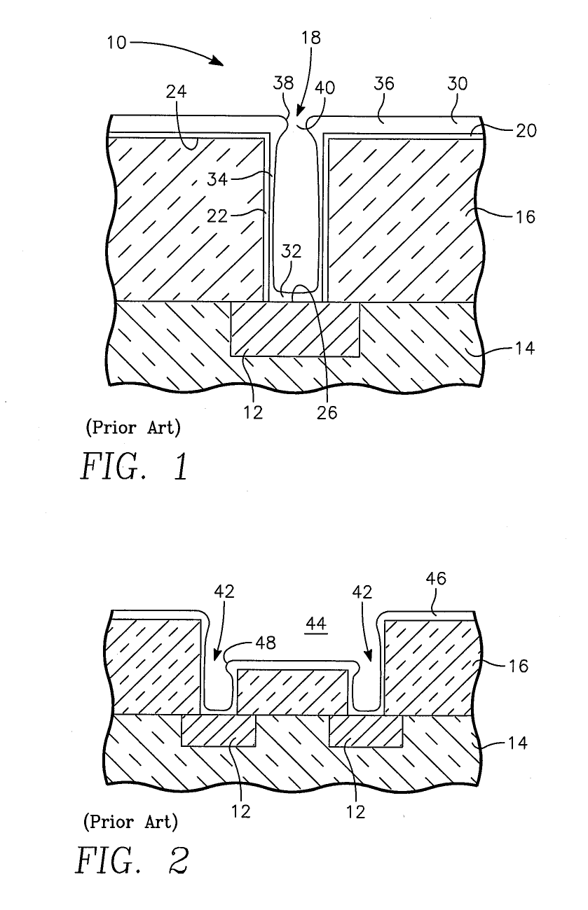

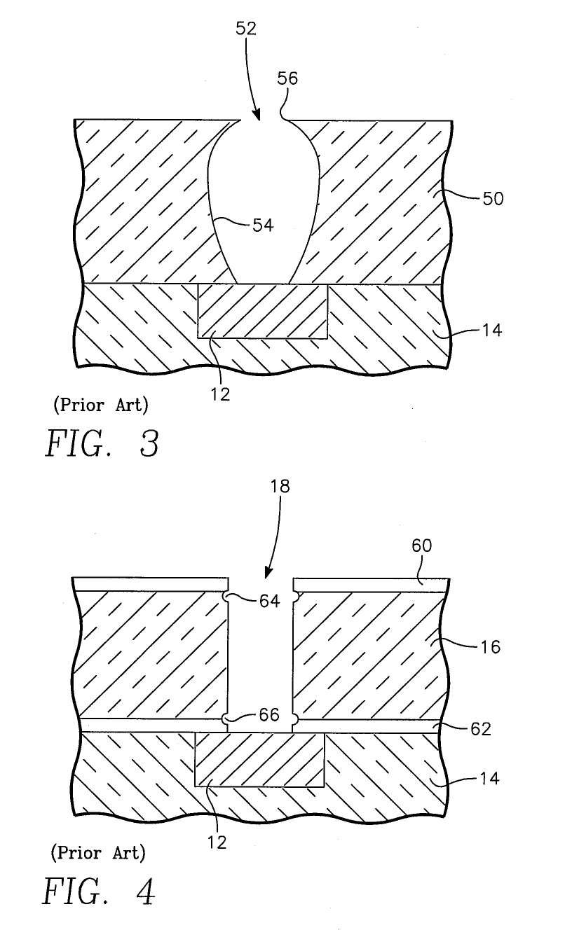

### DETAILED DESCRIPTION OF THE PREFERRED EMBODIMENTS

Filling copper into high aspect-ratio holes such as vias and dual-damascene interconnects is facilitated by a combination of copper sputter deposition and argon sputter etching preferably performed in a single copper sputter chamber. The energetic sputter etching reduces the size of overhangs and also tends to redistribute copper into concave portions of the sidewalls in a process often referred to as resputtering.

Although some aspects of the invention are not so limited, the sputter deposition and sputter etching are preferably performed in a chamber with an RF coil which can excite an argon plasma for the argon sputter etch with limited if any sputtering of the copper target during the etch phase. Ding et al. have described a sputter deposition/etch sequence of a tantalum barrier in an inductively coupled sputter chamber in U.S. patent application Ser. No. 10/915,139, filed Aug. 9, 2004, now published as U.S. patent application publication 2006/0030151. A similar sputter chamber 70 is illustrated in the cross-sectional view of FIG. 5. A vacuum chamber 72 is formed generally symmetrically about a central axis 74. It includes a main chamber 76, a lower adapter 78, and an upper adapter 80, all electrically grounded and vacuum sealed to each other. Most of the complex ports for wafer transfer, vacuum pumping and gas supply are incorporated into the main chamber 76 while the simpler adapters 78, 78 may be more easily designed and fabricated with selected heights and shield support depending on the application and the desired spacing between target and wafer. A trough-shaped lower shield 90 and a middle shield 92 are supported respectively on the lower adapter 78 and the upper adapter 80 and electrically grounded to them. An upper shield 94 is supported on an isolator 96 and left electrically floating. The shields 90, 92, 94 protect the walls of the chamber 72 from deposition. The lower two grounded shields 90, 92 act as anodes for the sputtering while the ungrounded upper shield 94 accumulates charge and repels electrons back into the plasma. An RF coil 100 is disposed just outside the periphery of the wafer in a lower half or third of the space between the target and the pedestal. Multiple insulating supports 102 held in the lower shield 90 support the RF coil 100 and also supply RF power and grounding to the RF coil. The coil 100 is preferably a single-turn, nearly tubular coil composed of copper and with a small gap between the closely spaced electrical leads for power and grounding.

A copper target 106 is supported on the upper adapter 80 through an isolator 108 electrically isolating the electrically biased target 106 from the grounded vacuum chamber and grounded shields 90, 92. At least the face of the target 106 is composed of at least 90 at % copper and possible intentional alloying and unintentional impurities totaling less than 10 at %. A pedestal 110 supports a wafer 112 to be sputter processed in opposition to the target 106. The RF coil 110 is placed in the lower half or even third of the chamber between the target 106 and pedestal 110 to generate a plasma near the wafer 112. A shadow ring 114 interlocking with the ascending lip of the cup-shaped lower shield 90 overhangs the peripheries of the wafer 112 and the pedestal 110 to protect them from sputter processing. A sidewall magnet system 116 is placed outside the lower adapter 78 on a level with and partially below the RF coil 100 to create a magnetic barrier against diffusion of the plasma to the chamber walls. The magnet system 116 may be an annular array of vertically polarized magnets or a DC coil arranged about the central axis 74.

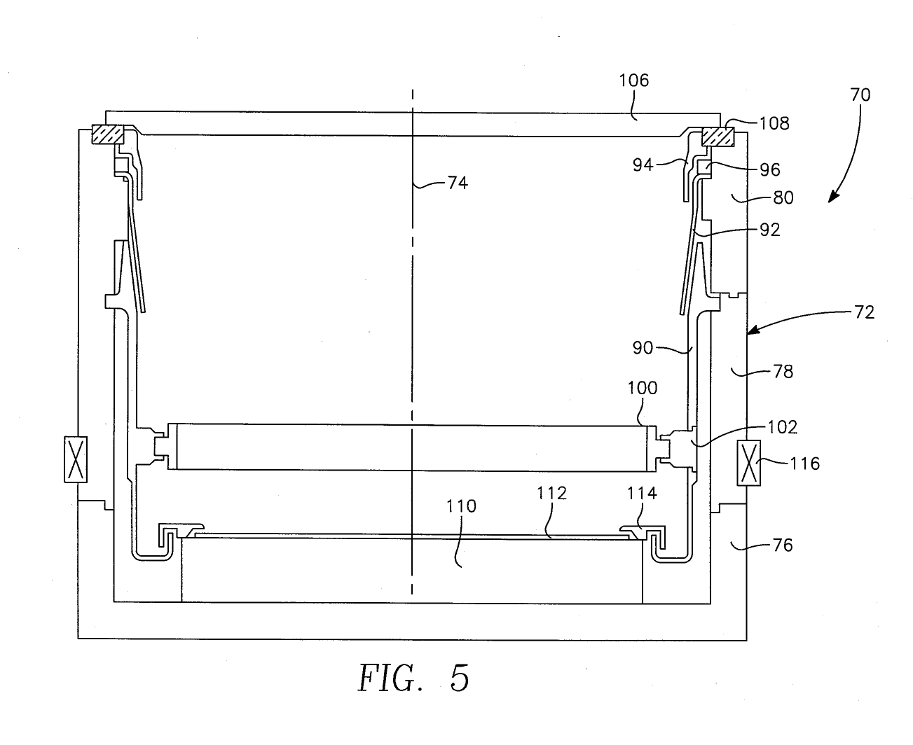

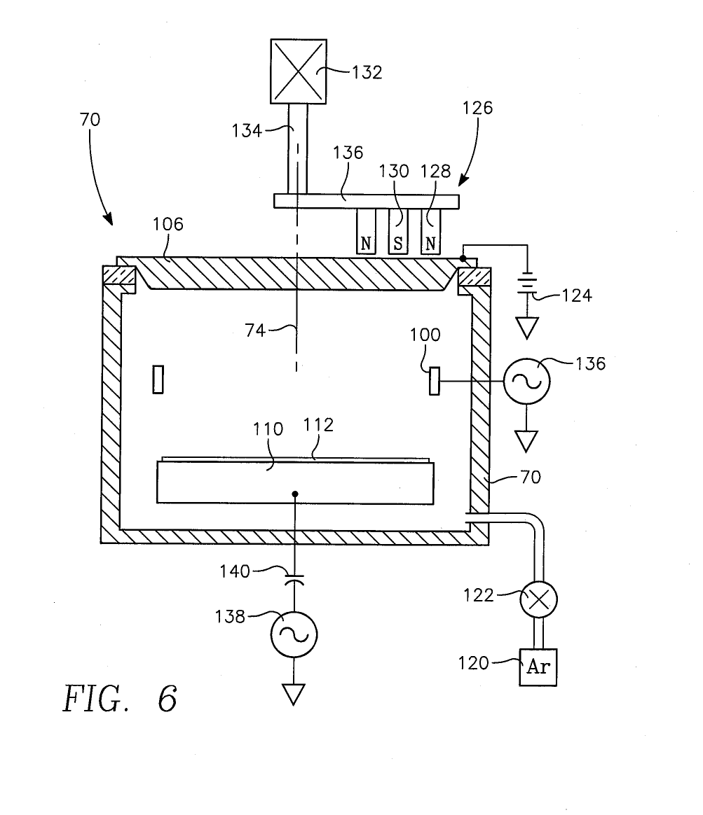

A functional cross-sectional view of the chamber is illustrated in FIG. 6. An argon gas source 120 supplies argon through a mass flow controller 122 into the chamber 70 as a sputter working gas or a sputtering etching gas. A DC power supply 124 applies a negative voltage to the target 106 to excite the argon into a plasma. The positive argon ions are attracted to the negatively biased target 106 to sputter copper from it. However, in self-sustained sputter of copper, once the plasma has been ignited the argon supply may be cut off and the target sputtering continues with sputtered copper ions being attracted back to the target 106 to sputter more copper.

A magnetron 126 positioned in back of the target 106 includes an outer pole 128 of one vertical magnetic polarity surrounding an inner pole 130 of the other polarity. The magnetron 126 is preferably strong, small, and unbalanced in the sense that the total magnetic intensity of the outer pole 128 is substantially larger than that of the inner pole 130 it surrounds. It projects a magnetic field in front of the target 106 to trap electrons and thereby increases the density of the plasma and hence the sputtering rate. A copper target is capable of self-sustained sputtering so that once the plasma has been excited, the argon pressure can be reduced even substantially to zero because the high-density plasma ionizes the sputtered copper atoms and the copper ions are partially attracted back to the target 106 to continue the sputtering. To produce more uniform target sputtering, the magnetron 126 although located away from the central axis 74 is rotated about it by a motor 132 rotating a rotary shaft 134 extending along the central axis 74 to more uniformly sputter the target 106. An arm 136 fixed to the rotary shaft 134 supports the magnetron 126 in its rotational movement.

A coil RF power supply 136 supplies RF power to the RF coil 100 to generate an argon plasma in a region removed from the target 106. Generally, the target 106 is DC powered for sputter deposition and the RF coil 100 is RF coil for sputter etching of the wafer 112. However, an RF supply may power the target sputtering.

A bias RF power supply 138 electrically biases the pedestal 110 through a capacitive coupling circuit 140. In the presence of a plasma, the capacitively coupled RF bias causes the pedestal 110 to develop a negative DC self-bias to attract and accelerate ions from the plasma to the wafer 112. The ions so attracted may be copper ionized atoms sputtered from the target 106 or argon ions primarily generated by the RF coil 100.

Such a sputter chamber can be used for a sequence of copper sputter deposition and sputter etch steps.

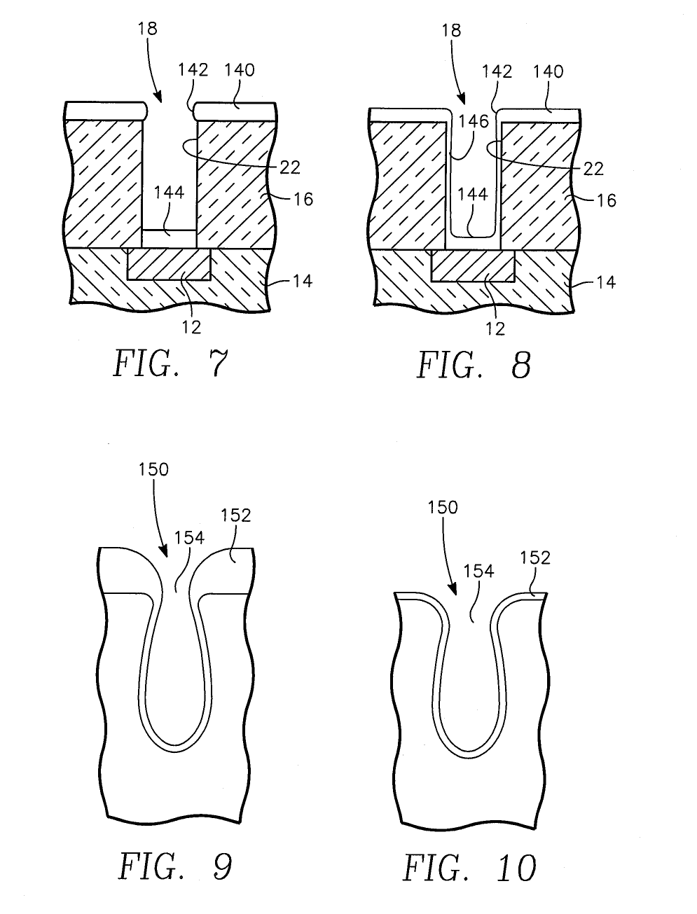

A highly biased sputter deposition of copper ions into a via hole 18 produces, as schematically illustrated in the cross-sectional view of FIG. 7, a thick copper field portion 140 of copper on top of the upper dielectric layer 14 with some overhangs 142 at the top corners of the via hole 18 and a somewhat thinner copper bottom portion 144 of copper on the bottom of the via 18 but very little deposition on the via sidewalls 22. On the other hand, a highly biased argon sputter etch of the structure of FIG. 7 substantially reduces the thickness of the field portion 140, as schematically illustrated in the cross-sectional view of FIG. 8, and reduces the extent of the overhangs 142 without simply pushing them down into the via hole 18. The argon sputter etch also somewhat reduces the thickness of the copper bottom portion 144 as the energetic argon ions sputter the copper from the copper bottom portion 144 and effectively transfer that sputter etched copper onto sidewall portions 146 on the via sidewalls 22. During the sputter deposition of FIG. 7, the RF coil may remain unpowered while the target is powered to produce a high fraction of copper ions. During the sputter etch of FIG. 8, the target may remain unpowered while the RF coil is powered to produce argon ions. In both cases, the wafer should be biased to attract and accelerate the copper or argon ions to a high energy and anisotropic flux deeply penetrating the via hole 18.

Scanning electron micrographs (SEMs) were taken to experimentally confirm the two-step process of deposition and etch. As illustrated in the cross-sectional view of FIG. 9, copper was sputtered into a 65 nm trench 150 with 38 kW of target power and 1000 W of wafer bias power to produce a copper film 152 having overhangs 154 which nearly close the trench 150. The wafer was then transferred to a pre-clean chamber configured for argon sputter etching of a biased wafer. After sputter etching, as illustrated in the cross-sectional view of FIG. 10, the field portion of the copper film 152 was substantially reduced in thickness to the extent that the overhang 154 were etched from above and thus effectively pulled back. The bottom portion was reduced somewhat in thickness while the sidewall portion grew.

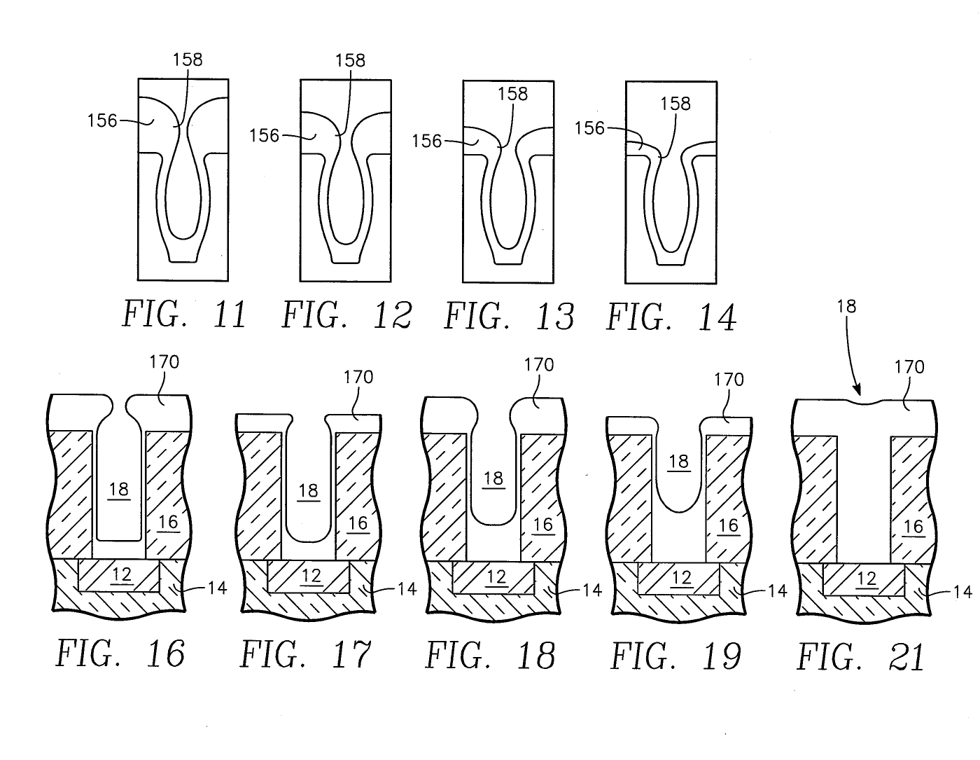

SEMS were taken in a more methodical set of experiments. Sputter deposition of 100 nm or 140 nm of copper into narrow trenches to form a copper film 156 produces severe overhangs 158, as illustrated in the cross-sectional view of FIG. 11. The overhangs 158 are located distinctly above the corner feature determined by the location of the underlying layer, for example, the barrier layer. Subsequent argon sputter etching to depths of 25 nm, 50 nm, and 70 nm as measured in the field region, produces the structures illustrated respectively in the cross-sectional views of FIGS. 12, 13, and 14. In other embodiments, these etch depths correspond to etch back ratios of 30%, 60%, and 80%. Increases in the extent of argon etching reduce the thickness of the field copper, decrease the projection of the overhangs 158, and generally lower the overhangs 158. We observe that once the narrowest portion of the throat is level with the underlying feature, further argon etching will not improve the overhangs 158.

The sputter etch step depends upon an energetic heavy ion, such as argon, being accelerated toward the wafer and sputtering material from the wafer. The energy E_{ION} of the singly charged ion depends on both the wafer floating voltage V_{FLOATING} and the plasma potential V_{PLASMA} depending upon wafer biasing according to

E_{ION}=eV_{FLOAT}+eV_{PLASMA}.

The floating potential V_{FLOAT} is typically less than 20 volts so the plasma potential V_{PLASMA} needs to be increased to obtain larger ion energy E_{ION} by increasing the RF power applied to the pedestal electrode. The ion energy can be effectively increased by increasing the plasma potential, for example, in a capacitively coupled plasma. Both plasma argon ions and copper ions sputtered from the target effectively sputter deposited copper and they have their respective advantages. A higher ionization density is typically available from an argon plasma but argon ions remove material at the bottom of the via and seem to degrade gap fill. On the other hand, energetic copper ions may simultaneously mill copper overhangs at the top of the gap and redistribute copper at the bottom of the gap. The RF coil 100 allows the copper ion energy to be decoupled from the copper ion flux. The RF coil 100 also allows very low pressure copper sputter etching with less than 0.4 milliTorr of argon.

The energy of the ion producing sputter etching affects the gap fill performance. Ions of higher energy more effectively remove the overhangs and open the throat to produce a better seed layer inside the via and to facilitate the ECP fill, thus promoting gap fill. An ion energy of 320 eV in a 70% etch back produces significantly better gap fill than an ion energy of 70 eV.

Temperature of the pedestal and hence the wafer during etching has also been found to play an important role in reducing the overhangs, presumably because of the reflow of copper at higher temperatures. As the wafer temperature increases from 28° C. to 150° C. with 1 kW of RF coil power and 1 kW of wafer bias power, the overhangs are significantly reduced. However, a further temperature increase to 250° C. produces significant copper overhangs but also significant bottom coverage. In general terms, a deposition temperature above 50 or 70° C. reduces the size of the overhangs to promote sputtering into the via holes. An even higher deposition temperature of above 150° C. promotes reflow of the already deposited copper into and within the via hole, thus improving sidewall coverage. However, a deposition temperature of above 250° C. causes thin layers of copper to agglomerate into localized islands and thus in some applications should be avoided in order to assure a continuous thin seed layer.

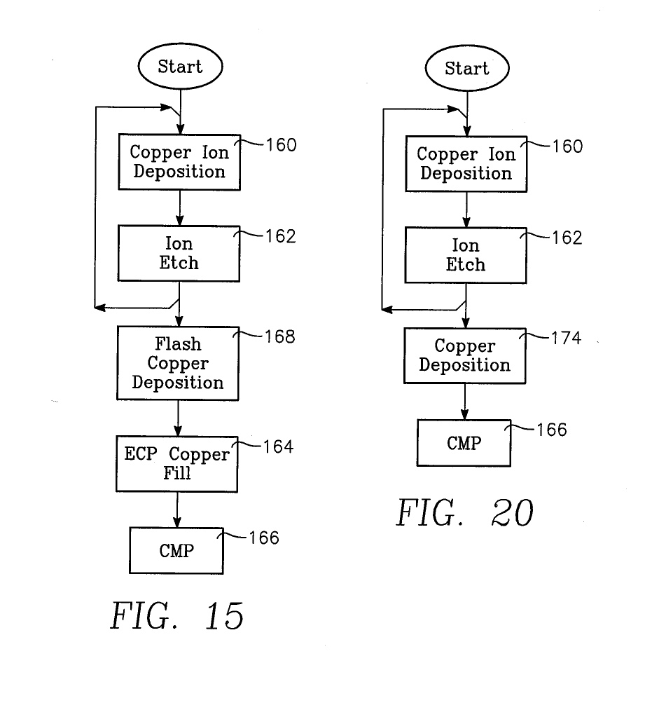

The ability to use the same chamber for both sputter deposition and sputter etch enables a variety of copper gap fill processes. As illustrated in the flow diagram of FIG. 15, a single or repeated sequence of a deposition step 160 and an etch step 162 opens up the via hole sufficiently that in an ECP step 164 copper is electroplated into the via hole and fills it and in a CMP step 166 excess copper outside of the via hole is removed by chemical mechanical polishing. The deposition step 160 produces a copper film 170, as illustrated in FIG. 16, with a thick field portion and a thin sidewall portion. An example of a recipe for the depositing copper onto a 300 mm wafer 160 includes applying between 20 and 56 kW of DC power to the target for a 300 mm wafer and between 150 and 1000 W of RF power to the pedestal at low chamber pressure after ignition.

The etch step 162, as illustrated in FIG. 17, reduces the field thickness and sputters some of the bottom portion onto the via sidewalls, particularly at the bottom. Several related methods achieving the etch step 162 involve DC magnetron sputtering with significant biasing of the wafer at 13.56 MHz or other frequency. However, the various etch methods differ in important details and produce somewhat different results in what may be tight requirements.

In one method, a relatively low level of DC power is applied to the target and the RF coil is strongly powered so that most of the wafer etching is effected by argon ions. Argon sputtering is effective at removing the copper bottom portion 32 but it seems to produce difficulties in copper filling of the hole.

In a second method, a high fraction of copper ionization is achieved and high bias power is applied to the wafer with little argon. As a result, the wafer etching is effected mainly by copper ions. For sputtering of copper, which allows self-sustained sputtering, the argon pressure may be reduced or its direct supply into the main chamber may be stopped. Copper sputter etching benefits from resputtering near the bottom and promotes copper hole filling.

Copper ion etching requires a magnetron producing a high copper ionization fraction and generally needs extra measures to achieve good etch uniformity. Such measures may include sidewall magnets or electromagnets adjacent the wafer. Copper ion sputtering may be accomplished in two different types of chambers. A capacitively coupled plasma may be produced of sufficient plasma density by high DC power applied to the target without the use of an RF coil to produce many copper ions. The sputtering process are at least close to those required for sustained self-sputtering. Capacitively coupled sputter etching, however, lacks the additional process control afforded by the RF coil. On the other hand, an inductively coupled plasma relies on the RF inductive coil to support a plasma near the wafer to increase the copper ionization. Inductively coupled generation of the plasma eases the requirements of high target power and strong magnetrons so auxiliary means for improving the etch uniformity are less important.

The generation of a high plasma density, particularly for argon ion etching, is promoted. dual-frequency (HF/VHF) biasing of the wafer, e.g., 13.56 MHz and 60 MHz, RF inductive coils intermediate the target and pedestal, or additional VHF biasing of the target, e.g. 60 MHz using an auxiliary electrode near the pedestal.

An example of an inductively coupled argon etch includes applying between 0 and 1 kW of DC power to the target, applying between 450 W and 3 kW of RF power at 2 MHz to the inductive coil, and applying between 400 to 1250 W of RF power at 13.56 MHz to the pedestal. The magnetron is relatively unimportant in the argon etch. The argon chamber pressure is maintained between 0.4 to 5 milliTorr and counter-rotating DC currents of −17 A and 17 A are applied to the bottom inner and outer electromagnets of the quadruple electromagnet array described by Gung et al. in U.S. patent application publication 2005/0263390, incorporated herein by reference.

An example of a recipe for a capacitively coupled argon ion etch includes applying between 1 and 10 kW of DC power to the target scanned by a strong magnetron, applying between 800 and 1250 W of RF bias power at 13.56 MHz to the pedestal while maintaining the argon chamber pressure between 0.4 and 1.5 milliTorr.

An example of a recipe for a capacitively coupled copper ion etch includes applying between 15 and 30 kW of DC power to the target scanned by the strong magnetron, applying between 1.5 and 2.5 kW of RF bias power at 13.56 MHz the pedestal while maintaining the argon chamber pressure between 0.4 and 1.5 milliTorr. The high bias power produces a net etch rate.

An example of a recipe for a dual-frequency pedestal includes applying to the pedestal between 500 to 200 W of VHF power at 60 MHz and between 400 and 1200 W of HF power at 13.56 MHz while maintaining an argon chamber pressure of between 2 and 30 milliTorr.

An example of a recipe for an auxiliary annular electrode located in the lower portion of the chamber includes applying 1 kW of VHF power at 60 MHz to the auxiliary electrode and 1 kW of HF power at 13.56 MHz to the pedestal with an argon pressure of 0.5 to 4 milliTorr.

An example of a recipe for a sputter etch chamber includes 1 to 2 kW of VHF power to a pedestal electrode, 1 to 2 kW of VHF power at 60 MHz on the target, and 0 to 1.2 kW of HF at 13.56 MHz on the wafer pedestal at 1 to 4 milliTorr of discharge pressure.

The structure of FIG. 17 may be sufficient for ECP filling. However, an optional flash copper deposition step 168 may be performed prior to the ECP copper fill step 164 to coat a thin layer of copper in any copper voids in the field region and particularly at the facet at the top of the via hole so as to assure continuity in the copper. The flash deposition step 168 may be performed in the same sputter chamber with minimal or no wafer biasing so the resputtering is minimized. In one approach it is preferred to produce a high ionization fraction but low resputtering ratio by applying between 15 and 40 kW of DC power to the target. The low wafer biasing produces a more isotropic copper ion sputter flux and reduces resputtering.

The process described above was used to fill a large number of vias in a test wafer in which the vias had critical dimensions of 35 to 50 nm with aspect ratios of above 5:1. The ECP filled structure was sectioned and SEMs were imaged. In a comparative experiment, 50 nm of seed copper was deposited and the via holes were then filled with ECP copper without intermediate etching. A significant fraction of the vias were formed with voids extending through their bottom third or half. When the copper seed was subjected to a 40% etch back with the argon sputter etching of the invention, the number of voided vias was reduced but not eliminated. When the etch back was extended to 70% and 80%, substantially all the vias were completely filled.

In a further embodiment of the process of the invention, the deposition and etch steps 160, 162 may be repeated to produce respectively the structures illustrated in the cross-sectional view of FIGS. 18 and 19. The effect is to increase the thickness of bottom and sidewall portions of the copper seed layer while maintaining the thickness of the field portion and the extent of the overhangs. At this point, the via hole 18 is even better prepared for filling by ECP copper. Two or three sequences of deposition and etch greatly promote the ECP gap filling.

In a yet further embodiment, the deposition and etch steps 160, 162 may be repeated yet further times, for example, for a total of three or four sequences, to almost fill the via hole 18, as shown in the flow diagram of FIG. 20. In this case, a final copper deposition step 174 completely fills the via hole 18, as illustrated in the cross-sectional view of FIG. 21 until the bottom of the remaining via hole 18 has have moved above the feature of the underlying layer. As a result, no copper electroplating is required, and the structure of FIG. 21 can be immediately subjected to CMP planarizing. The final copper deposition step does not operate upon a narrow via hole remaining in the copper so that strong wafer biasing is not required and it may approximate a final copper flash step.

It is possible to adapt the invention to reduce the amount of wafer biasing between subsequent sputter deposition steps.

It is possible to practice the invention in separate sputter deposition and sputter etching chambers.

It is possible to adapt the invention to reduce the amount of wafer biasing between subsequent sputter deposition steps.

It is possible to practice the invention in separate sputter deposition and sputter etching chambers.

The invention provides several fabrication methods, which may be used on available commercial equipment, of sputtering a copper seed layer into via holes of increased aspect ratio.

1. A copper deposition process for a copper metallization formed in a hole in a dielectric layer performed in a magnetron sputter chamber having a copper target and a pedestal electrode supporting a substrate to be sputter processed, comprising the steps of:
a first deposition step including applying a first target level of DC power to the copper target to excite a first plasma within the chamber to sputter copper from the target and electrically biasing the pedestal electrode with a first bias level of RF power to deposit copper upon the substrate; and
a subsequent etch step performed under different process conditions to excite a second plasma within the chamber and electrically biasing the pedestal with a second bias level of RF power to sputter etch with ions the copper deposited on the substrate.

2. The process of claim 1,
wherein the chamber includes an RF coil wrapped around the chamber, and
wherein the etch step includes applying less DC power than the first target level to the copper target, admitting argon into the chamber, applying RF power to the coil, and sputter etching the substrate with argon ions in the second plasma.

3. The process of claim 1,
wherein no more than 1.4 milliTorr of argon is admitted into the chamber during the etch step, and
wherein the etch step includes applying a second target level of DC power to the copper target and sputter etching the substrate with copper ions in the second plasma.

4. The process of claim 1,
wherein the chamber includes an RF coil wrapped around the chamber, and
wherein the etch step includes applying RF power to the coil.

5. The process of claim 1, further comprising a subsequent step of filling a remaining portion of the hole with copper in an plating process.

6. The process of claim 1, further comprising a subsequent second deposition step of sputtering copper from the target onto the substrate.

7. The process of claim 6, wherein the subsequent second deposition step includes applying a third bias level of RF power less than the first bias level to the pedestal electrode.

8. The process of claim 7, wherein the second deposition step includes either electrically floating the pedestal electrode or electrically biasing the pedestal electrode with a first bias level of RF power less than first bias level.

9. The process of claim 6 wherein the first deposition step and etch step are repeated a plurality of times prior to the second deposition step.

10. The process of claim 9, further comprising subsequently chemically mechanically polishing the substrate without an intermediate copper electroplating process.

11. The process of claim 9, wherein the first and second deposition steps and the etching steps fill the hole with copper.
